(19) United States
(12) Patent Application Publication
(10) Pub. No.: US 2026/0286521 A1
(43) Pub. Date: Sep. 24, 2026

(54) WAFER TREATING METHOD

(71) Applicant: ASAHI-UTOU TECHNOLOGY CO., LTD., Hsinchu County (TW)

(72) Inventor: Chun-Hui Wang, Hsinchu City (TW)

(21) Appl. No.: 19/683,407

(22) Filed: May 20, 2026

Related U.S. Application Data
(62) Division of application No. 19/078,708, filed on Mar. 13, 2025.

(30) Foreign Application Priority Data
Jan. 6, 2025 (TW) 114100398

(51) Int. Cl. C23C 16/455; C23C 16/44; C23C 16/458; C23C 16/46

(52) U.S. Cl. CPC C23C 16/45548; C23C 16/4408; C23C 16/4412; C23C 16/45565; C23C 16/4557; C23C 16/4586; C23C 16/46

(57) ABSTRACT

A wafer treating method includes step S10: opening a first top supply valve to supply a first carrier gas to a processing chamber, and opening a second side supply valve to supply a first precursor to the processing chamber; step S20: closing the first top supply valve and the second side supply valve; step S30: opening the second top supply valve to supply a second precursor to the processing chamber, and opening the first side supply valve to supply a second carrier gas to the processing chamber; step S40: closing the second top supply valve and the first side supply valve; and step S50: repeating the steps S10 through S40 for a predetermined number of times, and exhausting the processing chamber with the gas extraction device.

### CROSS-REFERENCE TO RELATED PATENT APPLICATION

This application is a divisional application of U.S. Patent Application No. 19/078,708, filed on Mar. 13, 2025, the entire disclosure of which is incorporated herein by reference.

### FIELD OF THE DISCLOSURE

The present disclosure relates to a wafer treating device and a wafer treating method, and more particularly to a wafer deposition device and a wafer deposition method.

### BACKGROUND OF THE DISCLOSURE

In the wafer treating process, wafers are typically processed by using etching, physical vapor deposition (PVD), chemical vapor deposition (CVD), plasma enhanced chemical vapor deposition (PECVD), atomic layer deposition (ALD), plasma enhanced atomic layer deposition (PEALD), pulsed deposited layer (PDL), plasma enhanced pulsed deposited layer (PEPDL), and photoresist removal.

For example, a plasma enhanced atomic layer deposition is a process in which multiple excited precursors are injected into a processing chamber to form a film on the wafer. In the related art, a heating platform is configured for carrying the wafer and heating the wafer, thereby forming a hot zone near the heating platform and a cold zone near the spraying head platform. Therefore, when the precursors are injected into the processing chamber, the precursors tend to diffuse from the hot zone to the cold zone, resulting in poor reaction uniformity of the wafers on the heating platform.

### SUMMARY OF THE DISCLOSURE

In response to the above-referenced technical inadequacy, the present disclosure provides a wafer treating device and a wafer treating method.

In order to solve the above-mentioned problems, one of the technical aspects adopted by the present disclosure is to provide a wafer treating device, which includes a processing chamber configured as an accommodation space for processing a wafer; a wafer supporting and heating unit disposed in the processing chamber for carrying the wafer; a shower head corresponding to the wafer supporting and heating unit and disposed at a top portion of the processing chamber; a first top gas source connected to the top portion of the processing chamber through a first top supply pipe, in which the first top supply pipe is provided with a first top supply valve; a second top gas source connected to the top portion of the processing chamber through a second top supply pipe, in which the second top supply pipe is provided with a second top supply valve; a first side gas source connected to a side wall of the processing chamber through a first side supply pipe, in which the first side supply pipe is provided with a first side supply valve; and a second side gas source connected to the side wall of the processing chamber through a second side supply pipe, in which the second side supply pipe is provided with a second side supply valve; in which the first top gas source and the second side gas source are configured to simultaneously supply gas to the processing chamber, and the first top gas source and the second top gas source do not simultaneously supply gas to the processing chamber.

In one of the possible or preferred embodiments, each of the first top gas source and the first side gas source is configured to supply a carrier gas, and each of the second top gas source and the second side gas source is configured to supply a precursor.

In one of the possible or preferred embodiments, the carrier gas is selected from the group consisting of argon, helium, nitrogen and a mixture thereof, and the precursor is selected from the group consisting of bis(diethylamino)silane (BDEAS), bis(t-butylamino)silane (BTBAS), tris(dimethylamino)silane (3DMAS), trimethylsilane (TMS), and a mixture thereof.

In one of the possible or preferred embodiments, the amount of the carrier gas is 10 sccm to 100 sccm.

In one of the possible or preferred embodiments, the second top gas source and the first side gas source are configured to simultaneously supply gas to the processing chamber, and the first side gas source and the second side gas source do not simultaneously supply gas to the processing chamber.

In one of the possible or preferred embodiments, the wafer treating device further includes a gas extraction device provided on another side wall of the processing chamber relative to the first side gas source and the second side gas source.

In one of the possible or preferred embodiments, the gas extraction device is indirectly connected to the processing chamber through a low-pressure chamber, and the pressure of the low-pressure chamber is lower than the pressure of the processing chamber.

In one of the possible or preferred embodiments, the processing chamber has a chamber temperature ranging from 80°C to 350°C.

In one of the possible or preferred embodiments, the processing chamber has a processing pressure ranging from 0.1 torr to 10 torr.

In one of the possible or preferred embodiments, the wafer treating device further includes a first top heater thermally coupled to the first top gas source, a second top heater thermally coupled to the second top gas source, a first side heater thermally coupled to the first side gas source, and a second side heater thermally coupled to the second side gas source.

In order to solve the above-mentioned problems, another one of the technical aspects adopted by the present disclosure is to provide a wafer treating method, which includes: step S10: opening the first top supply valve to supply a first carrier gas to the processing chamber, and opening the second side supply valve to supply a first precursor to the processing chamber; step S20: closing the first top supply valve and the second side supply valve; step S30: opening the second top supply valve to supply a second precursor to the processing chamber, and opening the first side supply valve to supply a second carrier gas to the processing chamber; step S40: closing the second top supply valve and the first side supply valve; and step S50: repeating the steps S10 through S40 for a predetermined number of times, and exhausting the processing chamber with the gas extraction device.

In one of the possible or preferred embodiments, each of the first carrier gas and the second carrier gas is selected from the group consisting of argon, helium, nitrogen and a mixture thereof, and each of the first precursor and the second precursor is selected from the group consisting of bis(diethylamino)silane (BDEAS), bis(t-butylamino)silane (BTBAS), tris(dimethylamino)silane (3DMAS), trimethylsilane (TMS), and a mixture thereof.

In one of the possible or preferred embodiments, the amount of each of the first carrier gas and the second carrier gas is 10 sccm to 100 sccm.

In one of the possible or preferred embodiments, the second top gas source and the first side gas source are configured to simultaneously supply gas to the processing chamber, and the first side gas source and the second side gas source do not simultaneously supply gas to the processing chamber.

In one of the possible or preferred embodiments, the gas extraction device is disposed on another side wall of the processing chamber relative to the first side gas source and the second side gas source.

In one of the possible or preferred embodiments, the wafer treating method further includes providing a low-pressure chamber between the processing chamber and the gas extraction device, wherein the pressure of the low-pressure chamber is lower than the pressure of the processing chamber.

In one of the possible or preferred embodiments, the wafer treating method further includes setting a chamber temperature of the processing chamber to a range from 80°C to 350°C.

In one of the possible or preferred embodiments, the wafer treating method further includes setting a processing pressure of the processing chamber to a range from 0.1 torr to 10 torr.

In one of the possible or preferred embodiments, the wafer treating method further includes thermally coupling a first top heater to the first top gas source to heat the first top gas source; thermally coupling a second top heater to the second top gas source to heat the second top gas source; thermally coupling a first side heater to the first side gas source to heat the first side gas source; and thermally coupling a second side heater to the second side gas source to heat the second side gas source.

Therefore, in the wafer treating device provided by the present disclosure, by virtue of “a processing chamber configured as an accommodation space for processing a wafer,” “a wafer supporting and heating unit disposed in the processing chamber for carrying the wafer,” “a shower head corresponding to the wafer supporting and heating unit and disposed at a top portion of the processing chamber,” “a first top gas source connected to the top portion of the processing chamber through a first top supply pipe that is provided with a first top supply valve,” “a second top gas source connected to the top portion of the processing chamber through a second top supply pipe that is provided with a second top supply valve,” “a first side gas source connected to a side wall of the processing chamber through a first side supply pipe that is provided with a first side supply valve,” “a second side gas source connected to the side wall of the processing chamber through a second side supply pipe that is provided with a second side supply valve,” “the first top gas source and the second side gas source being configured to simultaneously supply gas to the processing chamber” and “the first top gas source and the second top gas source being configured to supply gas to the processing chamber at different times,” the gas distribution in the processing chamber can be uniform to improve the uniformity of film formation.

Furthermore, in the wafer treating method provided by the present disclosure, by virtue of “step S10: opening the first top supply valve to supply a first carrier gas to the processing chamber, and opening the second side supply valve to supply a first precursor to the processing chamber,” “step S20: closing the first top supply valve and the second side supply valve,” “step S30: opening the second top supply valve to supply a second precursor to the processing chamber, and opening the first side supply valve to supply a second carrier gas to the processing chamber,” “step S40: closing the second top supply valve and the first side supply valve” and “step S50: repeating the steps S10 through S40 for a predetermined number of times, and exhausting the processing chamber with the gas extraction device,” the gas distribution in the processing chamber can be uniform to improve the uniformity of film formation.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a wafer treating device according to a first embodiment of the present disclosure;

FIG. 2 is a schematic view of the wafer treating device according to a second embodiment of the present disclosure;

FIG. 3 is a schematic view of the wafer treating device according to a third embodiment of the present disclosure; and

FIG. 4 is a flowchart of a wafer treating method according to the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

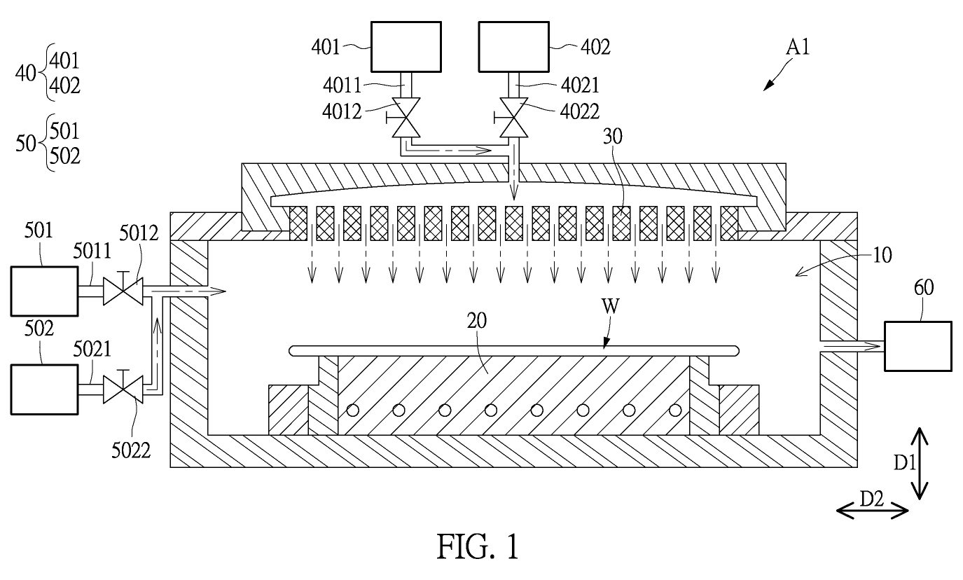

Referring to FIG. 1, a first embodiment of the present disclosure provides a wafer treating device A1 (or a wafer processing apparatus), which includes a processing chamber 10, a wafer supporting and heating unit 20 (or a wafer heating substrate), a shower head 30 (or a spraying head), a top gas source 40, a side gas source 50 and a gas extraction device 60. The processing chamber 10 may be an accommodation space for processing at least one wafer W, and the wafer supporting and heating unit 20 can be disposed in the processing chamber 10 to support the wafer W. The shower head 30 corresponding to the wafer supporting and heating unit 20 can be disposed at the top portion of the processing chamber 10 (i.e., located above the wafer supporting and heating unit 20). The top gas source 40 can be connected to the top portion of the processing chamber 10, and the side gas source 50 can be connected to a side wall of the processing chamber 10. The gas extraction device 60 can be disposed on another side wall of the processing chamber 10 relative to the side gas source 50.

In one embodiment, the wafer W may have blind holes or trenches. Furthermore, the wafer W may have a high aspect ratio (AR), for example, the aspect ratio of the wafer W can be 10:1, 11:1, 12:1, 13:1, 14:1 or 15:1. However, the above example is only one feasible embodiment and is not intended to limit the present disclosure. The wafer supporting and heating unit 20 may be electrically coupled to a power source (not shown). For example, the power source may be a bias device, the precursor is easily attracted to the wafer W and falls into the high aspect ratio structure under the bias effect, thereby helping to improve the coating efficiency and uniformity.

The top gas source 40 may include a first top gas source 401 (or a first top gas source generator) and a second top gas source 402 (or a second top gas source generator). The first top gas source 401 and the second top gas source 402 may evenly inject (uniformly supply) gas into the processing chamber 10 along the first direction D1. The first top gas source 401 is connected to the top portion of the processing chamber 10 through a first top supply pipe 4011, and a first top supply valve 4012 may be provided on the first top supply pipe 4011 to control the gas supply of the first top gas source 401. The second top gas source 402 is connected to the top portion of the processing chamber 10 through a second top supply pipe 4021, and a second top supply valve 4022 may be provided on the second top supply pipe 4021 to control the gas supply of the second top gas source 402.

The side gas source 50 may include a first side gas source 501 (or a first side gas source generator) and a second side gas source 502 (or a second side gas source generator). The first side gas source 501 and the second side gas source 502 may evenly inject (uniformly supply) gas into the processing chamber 10 along the second direction D2 perpendicular to the first direction D1. The first side gas source 501 is connected to the side wall of the processing chamber 10 through a first side supply pipe 5011, and a first side supply valve 5012 may be provided on the first side supply pipe 5011 to control the gas supply of the first side gas source 501. The second side gas source 502 is connected to the side wall of the processing chamber 10 through a second side supply pipe 5021, and a second side supply valve 5022 may be provided on the second side supply pipe 5021 to control the gas supply of the second side gas source 502.

The first top gas source 401 and the first side gas source 501 can provide carrier gases to the processing chamber 10. For example, the carrier gas may be argon, helium, nitrogen, or a mixture thereof. The second top gas source 402 and the second side gas source 502 may provide precursors to the processing chamber 10. For example, the precursor may be bis(diethylamino)silane (Si[N(C₂H₅)₂]₂H₂, BDEAS), bis(t-butylamino)silane (SiH₂[NH(C₄H₉)]₂, BTBAS), tris(dimethylamino)silane (Si[N(CH₃)₂]3H, 3DMAS), trimethylsilane (SiC₃H₁₀, TMS), or a mixture thereof.

Furthermore, the gases provided by the first top gas source 401 and the second top gas source 402 may be mixed in the top space of the processing chamber 10 and the shower head 30 and then supplied to the wafer W.

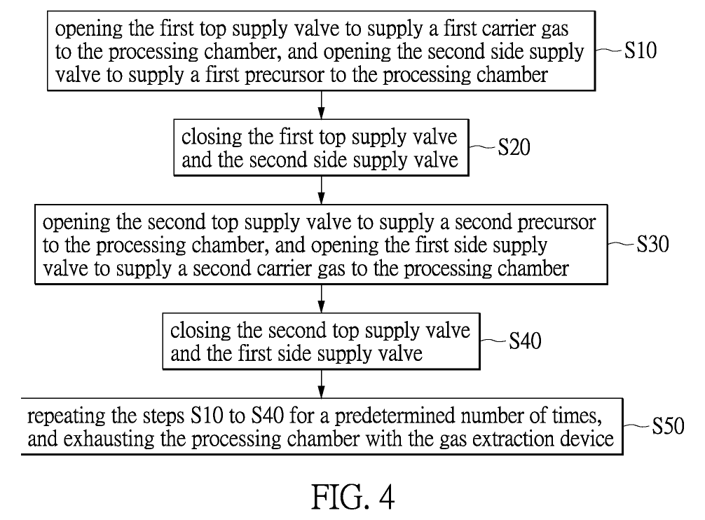

In the present disclosure, referring to FIG. 4, the present disclosure provides a wafer treating method (or a wafer processing method), which includes at least the following steps: step S10: opening the first top supply valve 4012 to supply the first carrier gas to the processing chamber 10, and opening the second side supply valve 5022 to supply the first precursor to the processing chamber 10; step S20: closing the first top supply valve 4012 and the second side supply valve 5022; step S30: opening the second top supply valve 4022 to supply the second precursor to the processing chamber 10, and opening the first side supply valve 5012 to supply the second carrier gas to the processing chamber 10; step S40: closing the second top supply valve 4022 and the first side supply valve 5012; and step S50: repeating the step S10 to step S40 for a predetermined number of times, and then exhausting the processing chamber 10 with the gas extraction device 60 (using the gas extraction device 60 to exhaust air from the processing chamber 10). The gas extraction device 60 can generate an exhaust gas flow in the second direction D2. When the deposition step is finished (after finishing the step S50), the gas extraction device 60 can be turned on to exhaust excess gas (remaining gas) from the processing chamber 10.

According to the above description, when the second top gas source 402 and the first side gas source 501 simultaneously supply gas to the processing chamber 10, the second top gas source 402 can inject (provide) the precursor along the first direction D1, and the first side gas source 501 can inject (provide) the carrier gas along the second direction D2, in which the amount of the carrier gas used is about 10 sccm to 100 sccm (such as any positive integer between 10 sccm and 100 sccm) to form a gas curtain to reduce the diffusion of the precursor to the side gas source under the influence of temperature. That is to say, the second top gas source 402 and the first side gas source 501 can supply gas to the processing chamber 10 at the same time, and the first side gas source 501 and the second side gas source 502 do not supply gas to the processing chamber 10 at the same time. It should be noted that sccm (standard cubic centimeter per minute) is a unit of gas mass flow rate, which means standard milliliters per minute.

In one embodiment, the present disclosure can use an ellipsometer to measure the film thickness (measuring the upper film thickness, the lower film thickness, the left film thickness, the right film thickness and the central film thickness). When the amount of carrier gas used is low, the right film thickness of the wafer W is greater than the left film thickness of the wafer W, and the non-uniformity of the film thickness is 4.29%. When the amount of carrier gas used is high, the film thickness on each side of the wafer W is roughly the same, and the non-uniformity of the film thickness is only 0.23%. It should be noted that although the uniformity of film thickness increases with the increase of the amount of carrier gas used, using too much carrier gas will increase the process cost and have limited effect in improving film thickness uniformity. Therefore, the preferred usage amount of the carrier gas is about 10 sccm to 100 sccm. In other words, when the amount of carrier gas used is less than 10 sccm, the problem of uneven film thickness cannot be overcome, and when the amount of carrier gas used is more than 100 sccm, the process cost will increase.

Similarly, when the first top gas source 401 and the second side gas source 502 simultaneously supply gas to the processing chamber 10, the second side gas source 502 can inject (provide) the precursors along the second direction D2, and the first top gas source 401 can inject (provide) the carrier gas along the first direction D1, and the amount of the carrier gas used is about 10 sccm to 100 sccm to form a gas curtain to reduce the diffusion of the precursor to the shower head 30 under the influence of temperature. That is to say, the first top gas source 401 and the second side gas source 502 can supply gas to the processing chamber 10 at the same time, and the first top gas source 401 and the second top gas source 402 do not supply gas to the processing chamber 10 at the same time. In addition, in one embodiment of the present disclosure, the chamber temperature of the processing chamber 10 may be 80°C to 350°C (such as any positive integer between 80°C and 350°C), and the processing pressure of the processing chamber 10 may be 0.1 torr to 10 torr (such as any positive integer between 0.1 torr and 10 torr). Preferably, the chamber temperature of the processing chamber 10 may be 100°C to 300°C, and the processing pressure of the processing chamber 10 may be 1 torr to 5 torr.

### Second Embodiment

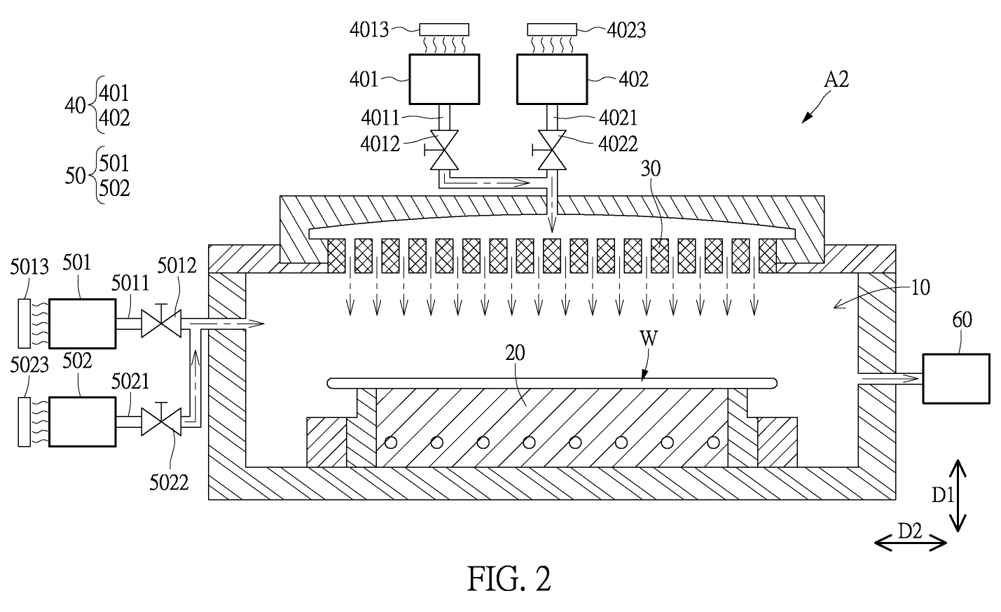

Referring to FIG. 2, a second embodiment of the present disclosure provides a wafer treating device A2, which includes a processing chamber 10, a wafer supporting and heating unit 20, a shower head 30, a top gas source 40, a side gas source 50 and a gas extraction device 60. The difference between the wafer treating device A2 of the second embodiment and the wafer treating device A1 of the first embodiment is that: the wafer treating device A2 may further include a first top heater 4013 thermally coupled to the first top gas source 401, a second top heater 4023 thermally coupled to the second top gas source 402, a first side heater 5013 thermally coupled to the first side gas source 501, and a second side heater 5023 thermally coupled to the second side gas source 502.

Furthermore, the heater can provide the gas source with energy required for the reaction of the carrier gas or the precursor. Specifically, the first top heater 4013 can be configured to heat the first top gas source 401, the second top heater 4023 can be configured to heat the second top gas source 402, the first side heater 5013 can be configured to heat the first side gas source 501, and the second side heater 5023 can be configured to heat the second side gas source 502.

### Third Embodiment

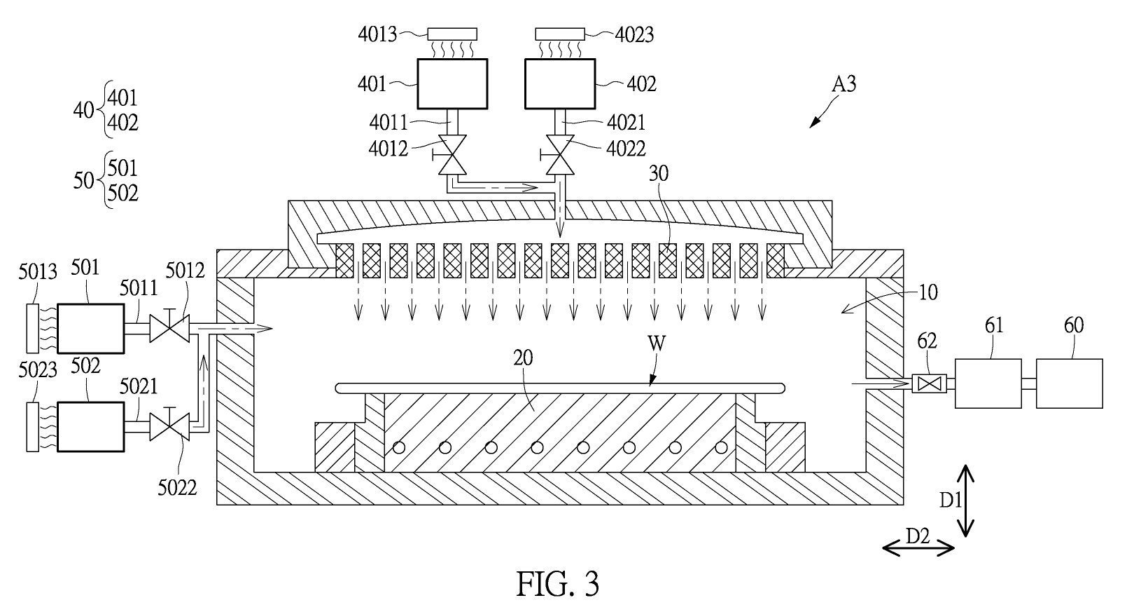

Referring to FIG. 3, a third embodiment of the present disclosure provides a wafer treating device A3, which includes a processing chamber 10, a wafer supporting and heating unit 20, a shower head 30, a top gas source 40, a side gas source 50 and a gas extraction device 60. The difference between the wafer treating device A3 of the third embodiment and the wafer treating device A1 of the first embodiment is that: the gas extraction device 60 of the wafer treating device A3 may further include a low-pressure chamber 61. The low-pressure chamber 61 is disposed between the processing chamber 10 and the gas extraction device 60, so that the gas extraction device 60 is not directly connected to the processing chamber 10, but is connected to the low-pressure chamber 61 to exhaust air from the low-pressure chamber 61.

Furthermore, the low-pressure chamber 61 may be maintained in a state close to the vacuum environment (that is to say, the pressure of the low-pressure chamber 61 is lower than the pressure of the processing chamber 10). Therefore, the pressure difference between the processing chamber 10 and the low-pressure chamber 61 can be used to make the gas flow from the processing chamber 10 to the low-pressure chamber 61. Furthermore, a valve 62 may be provided between the processing chamber 10 and the low-pressure chamber 61 to control the gas flow (or the gas flow rate). Specifically, when the deposition step is performed, the valve 62 can be closed to maintain the pressure in the processing chamber 10. After the deposition step is completed, the valve 62 can be opened to remove excess gas out of the processing chamber 10.

It is further explained that the present disclosure does not particularly limit the number of the first top gas source 401, the second top gas source 402, the first side gas source 501 and the second side gas source 502. For example, the present disclosure may use a plurality of second top gas sources 402 and/or a plurality of second side gas sources 502 to provide different types of precursors.

### Beneficial Effects of the Embodiments

In conclusion, one of the beneficial effects of the present disclosure is that in the wafer treating device provided by the present disclosure, by virtue of “a processing chamber configured as an accommodation space for processing a wafer,” “a wafer supporting and heating unit disposed in the processing chamber for carrying the wafer,” “a shower head corresponding to the wafer supporting and heating unit and disposed at a top portion of the processing chamber,” “a first top gas source connected to the top portion of the processing chamber through a first top supply pipe that is provided with a first top supply valve,” “a second top gas source connected to the top portion of the processing chamber through a second top supply pipe that is provided with a second top supply valve,” “a first side gas source connected to a side wall of the processing chamber through a first side supply pipe that is provided with a first side supply valve,” “a second side gas source connected to the side wall of the processing chamber through a second side supply pipe that is provided with a second side supply valve,” “the first top gas source and the second side gas source being configured to simultaneously supply gas to the processing chamber” and “the first top gas source and the second top gas source being configured to supply gas to the processing chamber at different times,” the gas distribution in the processing chamber can be uniform to improve the uniformity of film formation.

Furthermore, in the wafer treating method provided by the present disclosure, by virtue of “step S10: opening the first top supply valve to supply a first carrier gas to the processing chamber, and opening the second side supply valve to supply a first precursor to the processing chamber,” “step S20: closing the first top supply valve and the second side supply valve,” “step S30: opening the second top supply valve to supply a second precursor to the processing chamber, and opening the first side supply valve to supply a second carrier gas to the processing chamber,” “step S40: closing the second top supply valve and the first side supply valve” and “step S50: repeating the steps S10 through S40 for a predetermined number of times, and exhausting the processing chamber with the gas extraction device,” the gas distribution in the processing chamber can be uniform to improve the uniformity of film formation.

More particularly, the amount of the carrier gas used is about 10 sccm to 100 sccm based on the amount of the precursor injected into the processing chamber from the second direction, to form a gas curtain. The gas curtain can prevent the precursor from diffusing to the shower head during the step of injecting the precursor into the processing chamber from the second direction, thereby avoiding the occurrence of poor wafer reaction uniformity. Similarly, in the precursor deposition step of injecting the precursor from the first direction, a carrier gas is injected into the second direction to form a gas curtain. The amount of the carrier gas used is about 10 sccm to 100 sccm based on the amount of the precursor injected from the first direction. The gas curtain can prevent the precursor from diffusing to the side gas source during the step of injecting the precursor into the processing chamber from the first direction, thereby avoiding the occurrence of poor wafer reaction uniformity.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A wafer treating method, comprising:
step S10: opening a first top supply valve to supply a first carrier gas to a processing chamber, and opening a second side supply valve to supply a first precursor to the processing chamber;
step S20: closing the first top supply valve and the second side supply valve;
step S30: opening a second top supply valve to supply a second precursor to the processing chamber, and opening a first side supply valve to supply a second carrier gas to the processing chamber;
step S40: closing the second top supply valve and the first side supply valve; and
step S50: repeating the steps S10 to S40 for a predetermined number of times, and exhausting the processing chamber with a gas extraction device.

2. The wafer treating method according to claim 1, wherein each of the first carrier gas and the second carrier gas is selected from the group consisting of argon, helium, nitrogen and a mixture thereof, and each of the first precursor and the second precursor is selected from the group consisting of bis(diethylamino)silane (BDEAS), bis(t-butylamino)silane (BTBAS), tris(dimethylamino)silane (3DMAS), trimethylsilane (TMS), and a mixture thereof.

3. The wafer treating method according to claim 1, wherein the amount of each of the first carrier gas and the second carrier gas is 10 sccm to 100 sccm.

4. The wafer treating method according to claim 1, wherein the second top supply valve is connected to a second top gas source, the first side supply valve is connected to a first side gas source, the second top gas source and the first side gas source are configured to simultaneously supply gas to the processing chamber, and the first side gas source and a second side gas source do not simultaneously supply gas to the processing chamber.

5. The wafer treating method according to claim 1, wherein the gas extraction device is disposed on a side wall of the processing chamber relative to a first side gas source and a second side gas source.

6. The wafer treating method according to claim 1, further comprising: providing a low-pressure chamber between the processing chamber and the gas extraction device, wherein the pressure of the low-pressure chamber is lower than the pressure of the processing chamber.

7. The wafer treating method according to claim 1, further comprising: setting a chamber temperature of the processing chamber to a range from 80°C to 350°C.

8. The wafer treating method according to claim 1, further comprising: setting a processing pressure of the processing chamber to a range from 0.1 torr to 10 torr.

9. The wafer treating method according to claim 1, further comprising: thermally coupling a first top heater to a first top gas source to heat the first top gas source; thermally coupling a second top heater to a second top gas source to heat the second top gas source; thermally coupling a first side heater to a first side gas source to heat the first side gas source; and thermally coupling a second side heater to a second side gas source to heat the second side gas source.
